(19) United States
(12) Patent Application Publication
(10) Pub. No.: US 2025/0393120 A1
(43) Pub. Date: Dec. 25, 2025

(54) STRETCHABLE CIRCUIT BOARD

(71) Applicant: MEKTEC CORPORATION, Tokyo (JP)

(72) Inventor: Takumi KANEKO, Tokyo (JP)

(73) Assignee: MEKTEC CORPORATION, Tokyo (JP)

(21) Appl. No.: 19/188,923

(22) Filed: Apr. 24, 2025

(30) Foreign Application Priority Data
Jun. 20, 2024 (JP) 2024-099414

(51) Int. Cl. H05K 1/02; H05K 1/18

(52) U.S. Cl. CPC H05K 1/0283; H05K 1/181; H05K 1/189; H05K 2201/0104; H05K 2201/09427; H05K 2201/09472; H05K 2201/10151

(57) ABSTRACT

Provided is a stretchable circuit board including a first stretchable base; a stretchable conductive layer; a second stretchable base; an adhesive; biological electrodes; external terminals; and terminal attachment members, in which each biological electrode and each external terminal are included in the stretchable conductive layer, the second stretchable base is disposed so as to face the first stretchable base with the stretchable conductive layer interposed therebetween, the adhesive is configured to fix the stretchable circuit board to a biological body, each terminal attachment member is attached to an attachment portion of a corresponding connection terminal of external device to electrically connect the external terminals to the connection terminals of the external device, at least a biological-body-side surface of each terminal attachment member is exposed on the adhesive, and each terminal attachment member is movable in an in-plane direction of the stretchable circuit board.

### CROSS-REFERENCES

This application claims priority from Japanese Patent Application No. 2024-099414 filed with the Japan Patent Office on Jun. 20, 2024, the entire content of which is hereby incorporated by reference.

### BACKGROUND

### 1. Technical Field

The present disclosure relates to a stretchable circuit board.

### 2. Related Art

There has been known a stretchable circuit board including a stretchable base and a stretchable conductive layer disposed on the stretchable base. This stretchable circuit board is used with fixed to, e.g., the skin of a biological body (see, e.g., JP-A-2021-34387). In the stretchable circuit board disclosed in JP-A-2021-34387, an external terminal in the stretchable conductive layer is provided with a terminal attachment member (in JP-A-2021-34387, described as a recess-projection fitting portion or a conductive hook, for example). The terminal attachment member is attached to a connection terminal of an external device. According to JP-A-2021-34387, when the terminal attachment member is attached to the connection terminal of the external device, the external terminal of the stretchable conductive layer is electrically connected to the connection terminal of the external device. This can reduce misalignment between the terminal attachment member and the external terminal and the connection terminal of the external device.

### SUMMARY

A stretchable circuit board according to the present embodiment incudes: a first stretchable base; a stretchable conductive layer; a second stretchable base; an adhesive; a plurality of biological electrodes; a plurality of external terminals; and a plurality of terminal attachment members, in which each of the plurality of biological electrodes and each of the plurality of external terminals are included in the stretchable conductive layer, the second stretchable base is disposed so as to face the first stretchable base with the stretchable conductive layer interposed therebetween, the adhesive is configured to fix the stretchable circuit board to a biological body, each of the plurality of terminal attachment members is attached to an attachment portion of a corresponding connection terminal of external device to electrically connect the external terminals to the connection terminals of the external device, at least a biological-body-side surface of each terminal attachment member is exposed on the adhesive, and each terminal attachment member is movable in an in-plane direction of the stretchable circuit board.

### BRIEF DESCRIPTION OF THE DRAWINGS

FIG. 1 is a plan view of a stretchable circuit board according to a first embodiment;

FIG. 2 is a schematic end view cut along A-A line of FIG. 1;

FIG. 3 is an exploded view of the stretchable circuit board according to the first embodiment, and shows a schematic end structure cut along A-A line of FIG. 1;

FIG. 4 is a schematic cut end view showing the stretchable circuit board according to the first embodiment and an external device;

FIG. 5A is a schematic view showing misalignment between a terminal attachment member and an external terminal of the stretchable circuit board and a connection terminal of the external device;

FIG. 5B is a schematic view showing a state in which misalignment between the terminal attachment member and the external terminal of the stretchable circuit board and the connection terminal of the external device is eliminated;

FIG. 6 is a schematic cut end view of a stretchable circuit board according to a first modification of the first embodiment;

FIG. 7 is an exploded view of a stretchable circuit board according to a second modification of the first embodiment, and shows a schematic cut end structure;

FIG. 8 is a schematic cut end view of a stretchable circuit board according to a second embodiment;

FIG. 9 is a schematic cut end view of a stretchable circuit board according to a third embodiment;

FIG. 10A is a schematic cut end view of a stretchable circuit board according to a fourth embodiment;

FIG. 10B is an enlarged view of a portion B shown in FIG. 10A; and

FIG. 11 is an exploded view of the stretchable circuit board according to the fourth embodiment, and shows a schematic cut end structure.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

However, as a result of study conducted by the present developer(s) et al., in terms of easy alignment of each of the plurality of terminal attachment members, i.e., in terms of easy connection of each of the plurality of external terminals to the corresponding connection terminal of the external device, there is still room for improvement in the stretchable circuit board disclosed in JP-A-2021-34387.

The present embodiments cope with the above-described problems. An object of the present embodiments is to provide a stretchable circuit board configured so that each of a plurality of external terminals can be connected to a corresponding connection terminal of an external device by easy alignment of each of a plurality of terminal attachment members.

According to the present embodiment, provided is a stretchable circuit board including a first stretchable base; a stretchable conductive layer; a second stretchable base; an adhesive; a plurality of biological electrodes; a plurality of external terminals; and a plurality of terminal attachment members, in which each of the plurality of biological electrodes and each of the plurality of external terminals are included in the stretchable conductive layer, the second stretchable base is disposed so as to face the first stretchable base with the stretchable conductive layer interposed therebetween, the adhesive is configured to fix the stretchable circuit board to a biological body, each of the plurality of terminal attachment members is attached to an attachment portion of a corresponding connection terminal of external device to electrically connect the external terminals to the connection terminals of the external device, at least a biological-body-side surface of each terminal attachment member is exposed on the adhesive, and each terminal attachment member is movable in an in-plane direction of the stretchable circuit board.

According to the present embodiment, each of the plurality of terminal attachment members can be easily aligned. Moreover, each of the plurality of external terminals can be easily connected to the corresponding connection terminal of the external device.

Hereinafter, the present embodiments and modifications thereof will be described with reference to the drawings. Note that in all the drawings, the same reference numerals are used to represent similar components. Moreover, description of the components with the same reference numerals will be omitted as necessary.

### First Embodiment

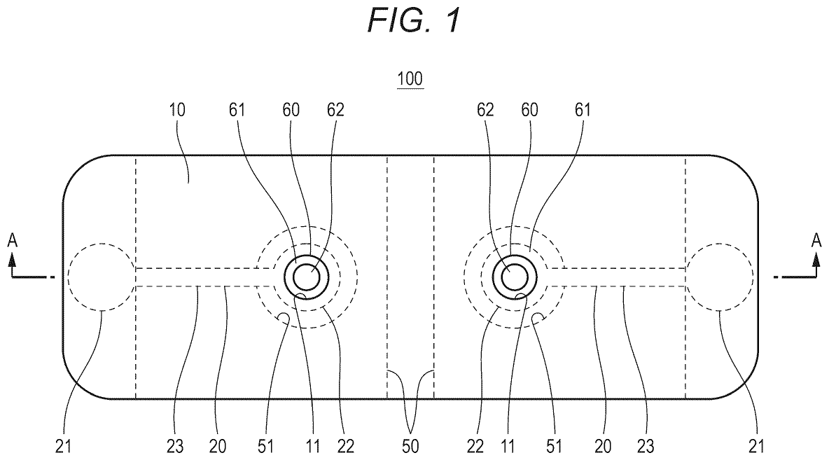

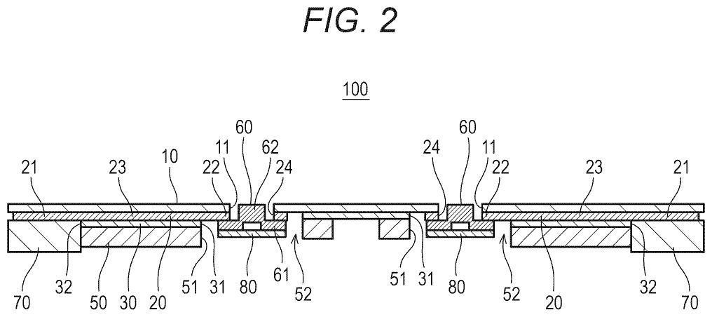

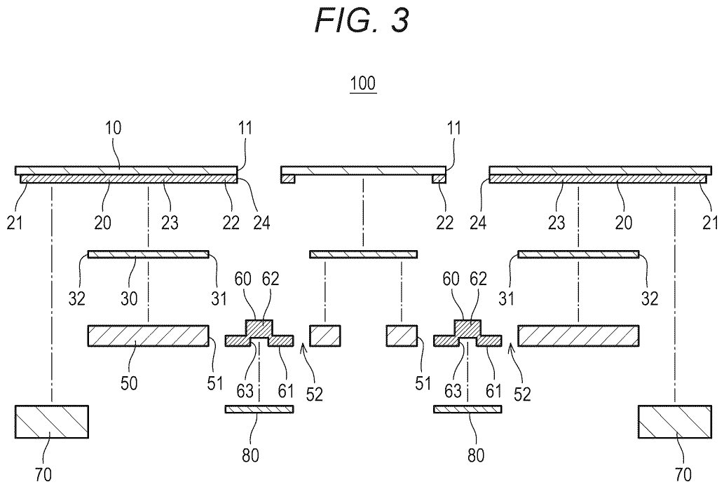

First, a first embodiment will be described with reference to FIGS. 1 to 5B. For the sake of convenience in description, the upper side in FIGS. 2 and 3 will be defined as upper (above, upper side). Moreover, the lower side in FIGS. 2 and 3 will be defined as lower (below, lower side). Note that a positional relationship in the upper-lower direction in the description is not necessarily coincident with that in the upper-lower direction when a stretchable circuit board 100 is used or stored.

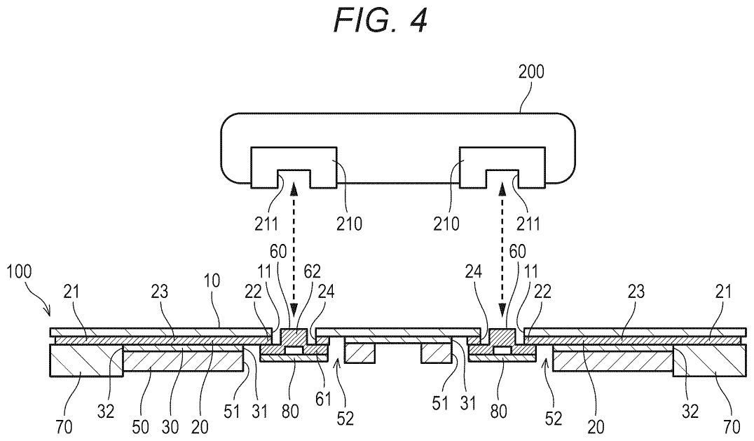

The stretchable circuit board 100 according to the present embodiment includes a first stretchable base 10, a stretchable conductive layer 20, and a second stretchable base 30. The second stretchable base 30 is disposed so as to face the first stretchable base 10 with the stretchable conductive layer 20 interposed therebetween. The stretchable conductive layer 20 includes a biological electrode 21, an external terminal 22, and a wiring portion 23 connecting the biological electrode 21 and the external terminal 22. The stretchable circuit board 100 further includes an adhesive layer (for example, adhesive 50 and biological conductive member 70) for fixing the stretchable circuit board 100 to a biological body (not shown), and a plurality of terminal attachment members 60. The terminal attachment member 60 is attached to an attachment portion 210 of an external device 200 (FIG. 4). With this configuration, a plurality of external terminals 22 is each electrically connected to corresponding connection terminals 211 of the external device 200. At least the biological-body-side surface of the terminal attachment member 60 is exposed on the adhesive 50. Here, the biological-body-side surface means the surface (lower surface in FIG. 2) of the terminal attachment member 60 facing the biological body to which the stretchable circuit board 100 is fixed. Moreover, the terminal attachment member 60 is movable in the in-plane direction of the stretchable circuit board 100.

According to the present embodiment, each terminal attachment member 60 is movable in the in-plane direction of the stretchable circuit board 100. Thus, in the in-plane direction of the stretchable circuit board 100, a distance between the plurality of terminal attachment members 60 is changeable. Consequently, each terminal attachment member 60 can be attached to the corresponding attachment portion 210 with aligned with such an attachment portion 210. That is, each of the plurality of terminal attachment members 60 can be easily aligned. Moreover, each of the plurality of external terminals 22 can be connected to the corresponding connection terminal 211. Note that in the technique disclosed in JP-A-2021-34387, a common non-stretchable base 12 is provided with a plurality of terminal attachment members (conductive hooks of this literature). Thus, it is difficult to change the distance between the plurality of terminal attachment members 60.

Hereinafter, the present embodiment will be described in more detail. The planar shape of the stretchable circuit board 100 is not particularly limited. One example of the planar shape is a substantially rectangular shape (for example, rectangular shape with rounded corners) as shown in FIG. 1. The numbers of biological electrodes 21, external terminals 22, wiring portions 23, and terminal attachment members 60 in the stretchable circuit board 100 are not particularly limited as long as these numbers are plural numbers. In the present embodiment, an example where two biological electrodes 21, two external terminals 22, and two terminal attachment members 60 are provided will be described. In this example, a correspondence relationship in number between the biological electrodes 21, the external terminals 22, the wiring portions 23, and the terminal attachment members 60 is one-to-one-to-one-to-one. Each stretchable conductive layer 20 includes one biological electrode 21, one external terminal 22, and one wiring portion 23. In the present embodiment, the number of stretchable conductive layers 20 is also two. The arrangement of the biological electrodes 21 and the arrangement of the external terminals 22 in the plane of the stretchable circuit board 100 are not particularly limited. In the example of FIG. 1, the biological electrodes 21 are each disposed at both end portions of the stretchable circuit board 100 in the longitudinal direction (right-left direction in FIG. 1) thereof. Moreover, the external terminals 22 are disposed at location closer to the center of the stretchable circuit board 100 in the longitudinal direction thereof. Each wiring portion 23 extends in the longitudinal direction of the stretchable circuit board 100. Moreover, such a wiring portion 23 connects each biological electrode 21 to the corresponding external terminal 22. The planar shape of the biological electrode 21 is not particularly limited. One example of the planar shape is a circular shape as shown in FIG. 1. The planar shape of the external terminal 22 is not particularly limited. One example of the planar shape is a circular shape as shown in FIG. 1. The planar shape of the wiring portions 23 is not particularly limited. One example of the planar shape is a linear shape narrower than the outer diameter of the biological electrode 21 and the outer diameter of the external terminal 22 as shown in FIG. 1.

In the present embodiment, the terminal attachment member 60 is conductive. As shown in FIGS. 2 and 3, the first stretchable base 10 is formed with an opening 11. Similarly, the external terminal 22 is formed with an opening 24. The terminal attachment member 60 is connected to a peripheral edge portion (the lower surface thereof) of the opening 24 of the external terminal 22. In addition, part of the terminal attachment member 60 is exposed (upward) through the opening 11 of the first stretchable base 10 and the opening 24 of the external terminal 22. The part of each terminal attachment member 60 is attached to the corresponding attachment portion 210 of the external device 200. With this configuration, each of the plurality of external terminals 22 is electrically connected to the corresponding connection terminal 211 of the external device 200 through the corresponding terminal attachment member 60 (see FIG. 4).

The external terminal 22 and the terminal attachment member 60 can be joined to each other, for example, by a hot-press method. In the hot-press method, a thermoplastic silver paste coating film exhibiting hot-melt properties is welded.

The stretchable conductive layer 20 is formed on the lower surface of the first stretchable base 10. The second stretchable base 30 is disposed on the lower surface side of the first stretchable base 10 and the lower surface side of the stretchable conductive layer 20. The adhesive 50 is disposed on the lower surface side of the second stretchable base 30. The first stretchable base 10 is formed with the opening 11 corresponding to the terminal attachment member 60. The external terminal 22 is formed with the opening 24 corresponding to the terminal attachment member 60. That is, two openings 11 and two openings 24 are formed. For example, the opening 11 of the first stretchable base 10 and the opening 24 of the external terminal 22 are formed in the same shape with the same dimension. Moreover, in plan view, the opening 11 and the opening 24 are formed at the same location. The second stretchable base 30 is formed with an opening 31 slightly larger than the opening 11 and the opening 24, for example. In plan view, the entireties of the opening 11 and the opening 24 are within the opening 31.

The adhesive 50 is an insulating adhesive. The adhesive 50 is formed of a coated adhesive material, for example. The adhesive material is not particularly limited. Examples of the adhesive material to be used may include acrylic-based resins.

The adhesive 50 is formed with an opening 51 at a location corresponding to the external terminal 22 and the terminal attachment member 60. Thus, the force of the adhesive 50 for restricting movement of the terminal attachment member 60 is reduced. Consequently, each terminal attachment member 60 is more easily movable in the in-plane direction of the stretchable circuit board 100.

In the present embodiment, in plan view, the entirety of the terminal attachment member 60 is within the opening 51. Thus, each terminal attachment member 60 is much more easily movable in the in-plane direction of the stretchable circuit board 100.

More specifically, in the present embodiment, there is a clearance 52 between the inner peripheral edge of the opening 51 of the adhesive 50 and the outer peripheral surface of the terminal attachment member 60. Thus, each terminal attachment member 60 can easily move in the opening 51 in the in-plane direction of the stretchable circuit board 100.

In the present embodiment, the clearance 52 surrounds the terminal attachment member 60 in an annular shape. Thus, the terminal attachment member 60 can easily move in all directions in the in-plane direction of the stretchable circuit board 100.

In the present embodiment, the second stretchable base 30 is formed with the opening 31 at a location corresponding to the external terminal 22 and the terminal attachment member 60. Thus, each terminal attachment member 60 can more easily move in the in-plane direction of the stretchable circuit board 100. In the present embodiment, for example, the opening 51 of the adhesive 50 and the opening 31 of the second stretchable base 30 are formed in the same shape with the same dimension, and are formed at the same location in plan view.

In the present embodiment, no second stretchable base 30 is disposed at a location corresponding to each biological electrode 21. That is, the second stretchable base 30 is formed with an opening 32 (missing portion of the second stretchable base 30) at the location corresponding to the biological electrode 21. Similarly, no adhesive 50 is also disposed at a location corresponding to the biological electrode 21. Thus, each biological electrode 21 is exposed on the lower surface side (biological body side) through the second stretchable base 30 and the adhesive 50.

Here, the first stretchable base 10 is a thin sheet material having stretchability. That is, the sheet material is stretchable at least in one direction in the in-plane direction of the first stretchable base 10. The stretchability described here indicates a property of stretching according to tension acting on the first stretchable base 10 and contracting according to compressive force acting on the first stretchable base 10. The first stretchable base 10 more changes its dimension and shape by stretching than by contracting.

A material forming the first stretchable base 10 is not particularly limited. Examples of this material may include elastomer materials such as nitrile rubber, latex rubber, and urethane-based elastomers. Particularly, a urethane-based elastomer sheet used for medical purposes is used so that high safety can be ensured even in a case where the stretchable circuit board 100 is bonded to the skin of a human body.

The thickness dimension of the first stretchable base 10 is not particularly limited. In terms of prevention of interference with stretching and contracting movement of the skin, the thickness dimension is preferably 50 μm or less and more preferably 5 μm or less, for example.

The maximum elongation of the first stretchable base 10 is preferably 10% or more, more preferably 50% or more, much more preferably 100% or more, and still much more preferably 200% or more. The maximum elongation of the first stretchable base 10 indicates the maximum value of the elongation by elastic deformation in one direction in the in-plane direction. The elongation means the ratio (elongation percentage) of the dimension of the first stretchable base 10 stretched in one direction in the in-plane direction by applied force to the dimension (dimension at an elongation of 0%) of the first stretchable base 10 to which no external force is applied. For example, when the elongation is 50%, the elongation percentage is 1.5 times the dimension at an elongation of 0%. When the elongation is 100%, the elongation percentage is twice the dimension at an elongation of 0%.

A material forming the second stretchable base 30 is not particularly limited. Examples of this material may include elastomer materials similar to the material of the first stretchable base 10. Note that the second stretchable base 30 is only required to be made of a material having at least insulating properties and stretchability. The second stretchable base 30 may be made of a material different from the material of the first stretchable base 10. The thickness dimension of the second stretchable base 30 is not particularly limited. In terms of prevention of interference with stretching and contracting movement of the skin, the thickness dimension is preferably 50 μm or less and more preferably 5 μm or less, for example.

The stretchable conductive layer 20 is, for example, a coating film including a conductive filler and a binder containing thermoplastic resin. With the binder contained in the stretchable conductive layer 20 and containing the thermoplastic resin, the stretchable conductive layer 20 can favorably follow stretching and contracting of the first stretchable base 10. Examples of the conductive filler include a conductive filler made of silver, gold, platinum, carbon, copper, aluminum, cobalt, nickel, or alloy thereof. For example, the conductive filler contained in the stretchable conductive layer 20 is silver. Examples of the thermoplastic resin may include thermoplastic elastomer materials such as urethane resin, acrylic resin, and silicone rubber. Preferably, as the thermoplastic resin, thermoplastic resin having a low Young's modulus is selected. With the low Young's modulus of the thermoplastic resin, the elasticity of the stretchable conductive layer 20 as the coating film can be equal to or less than the elasticity of the first stretchable base 10. One elastomer material may be used alone. Alternatively, a plurality of elastomer materials may be used in combination. The stretchable conductive layer 20 is formed, for example, by a printing method. The printing method is not particularly limited. Examples of the printing method include a screen printing method, an inkjet printing method, a gravure printing method, and an offset printing method. The stretchable conductive layer 20 can transmit an electric signal or current. More specifically, in the present embodiment, the biological electrode 21 contacts the skin of the biological body. The external device 200 can acquire, for example, a biological signal including a brain wave, a muscle potential, and an electrocardiogram from the biological body through the wiring portion 23, the external terminal 22, and the terminal attachment member 60.

When the first stretchable base 10 and the second stretchable base 30 are joined to each other, the stretchable conductive layer 20 is first printed on the first stretchable base 10. Thereafter, the second stretchable base 30 is stacked on the first stretchable base 10 with aligned with the first stretchable base 10. Then, the first stretchable base 10 and the second stretchable base 30 stacked on each other are heated and pressurized. As a result, the first stretchable base 10 and the second stretchable base 30 can be fused to each other. Examples of the heating technique to be employed may include a laminating technique with a heating roll and a hot-press technique.

The shape and structure of the terminal attachment member 60 are not particularly limited. In the present embodiment, the shape of the terminal attachment member 60 has, for example, a discoid flange 61 and a projection 62. The projection 62 has a smaller diameter than the diameter of the flange 61, and projects upward from a center portion of the upper surface of the flange 61. For example, a recess 63 is formed in a center portion of the lower surface of the flange 61.

In the present embodiment, the upper surface of the flange 61 of the terminal attachment member 60 is connected so as to extend around the peripheral edge portion (the lower surface thereof) of the opening 24 of the external terminal 22. The projection 62 of the terminal attachment member 60 and a portion of the upper surface of the flange 61 closer to the center with respect to a portion connected to the lower surface of the external terminal 22 are exposed to above (the upper surface side of the stretchable circuit board 100) through the opening 11 of the first stretchable base 10 and the opening 24 of the external terminal 22.

Note that FIG. 2 shows the upper surface of the projection 62 as if such an upper surface is flush with the upper surface of the first stretchable base 10. Actually, for example, the upper-lower dimension of the terminal attachment member 60 is greater than the total of the upper-lower dimensions (thickness dimensions) of portions of the stretchable circuit board 100 other than the portion provided with the terminal attachment member 60. Thus, the projection 62 projects upward beyond the upper surface of the first stretchable base 10.

In the present embodiment, the terminal attachment member 60 is made of a magnetic material attracted by a magnet or a magnet. As one example, the terminal attachment member 60 is not made of the magnet, but is made of the magnetic material such as iron. On the other hand, the attachment portion 210 of the external device 200 is made of a magnet or a magnetic material attracted by a magnet. As one example, the attachment portion 210 is made of the magnet (permanent magnet). The connection terminal 211 of the attachment portion 210 has a recess in which the projection 62 is to be fitted. The projection 62 is fitted in the connection terminal 211, and the terminal attachment member 60 is connected to the connection terminal 211. As described above, the projection 62 projects upward beyond the upper surface of the first stretchable base 10. Thus, the projection 62 can be easily fitted in the connection terminal 211 of the external device 200. With the magnetic force of the connection terminal 211, the projection 62 fitted in the connection terminal 211 is stably maintained. Note that the projection 62 is fitted in the connection terminal 211 with the magnetic force of the connection terminal 211. Thus, the fitting can be made with a so-called click feeling.

Each biological electrode 21 is provided with the biological conductive member 70 on the lower surface side. The biological conductive member 70 is an adhesive layer having conductivity. When the stretchable circuit board 100 is bonded to the skin of the biological body, each biological electrode 21 can be in conduction with the skin of the biological body through the biological conductive member 70. Examples of the biological conductive member 70 include hydrogel.

Note that in the present embodiment, no adhesive 50 is provided, for example, at a center portion of the stretchable circuit board 100 in the longitudinal direction thereof. That is, the stretchable circuit board 100 has a structure with two right and left divided adhesives 50. The biological conductive member 70 is disposed at each of both right and left end portions of the stretchable circuit board 100 in the longitudinal direction thereof.

The stretchable circuit board 100 further includes an insulating coating 80. The insulating coating 80 covers the surface (lower surface) of each terminal attachment member 60 facing the biological body. Thus, when the stretchable circuit board 100 is bonded to the skin of the biological body, conduction between each terminal attachment member 60 and the skin can be reduced. Here, the insulating coating 80 preferably has non-adhesiveness. In the present embodiment, the insulating coating 80 does not have adhesiveness. Thus, each terminal attachment member 60 can more easily move in the in-plane direction of the stretchable circuit board 100. The insulating coating 80 having the non-adhesiveness means that the adhesiveness of the insulating coating 80 is lower than the adhesiveness of the adhesive 50. The insulating coating 80 is, for example, a non-stretchable resin layer (resin sheet). Alternatively, the insulating coating 80 has, for example, flexibility and a higher Young's modulus than that of the first stretchable base 10. The stretchability of the insulating coating 80 is lower than the stretchability of the first stretchable base 10, the stretchable conductive layer 20, the second stretchable base 30, the adhesive 50, and the biological conductive member 70. The insulating coating 80 is a member which does not substantially stretch and contract much. The material of the insulating coating 80 is not particularly limited. Examples of this material include synthetic resins having low sliding properties, corrosion resistance, and high strength, such as polyethylene terephthalate (PET), polyethylene naphthalate (PEN), polyimide (PI), polyphenylene sulfide (PPS), and fluorine resin. As the material of the insulating coating 80, for example, a paper material having reasonable durability, such as cellulose nanofiber paper, may be used. Note that the insulating coating 80 may be formed of a coating film (coating) of a resin material formed on the lower surface (bottom surface) of the terminal attachment member 60.

The adhesive 50 preferably has a single-film structure with adhesive resin. In the present embodiment, the adhesive 50 has a single-film structure with adhesive resin. That is, the configuration of the adhesive 50 does not have a support film such as a non-woven fabric layer, for example. Thus, favorable stretchability of the adhesive 50 can be ensured. Note that the present embodiment is not limited to this example. As long as sufficient stretchability (stretchability to such an extent that movement of the terminal attachment member 60 in the in-plane direction of the stretchable circuit board 100 is not interfered) of the adhesive 50 can be ensured, the adhesive 50 may include, for example, a support film such as a non-woven fabric layer.

Here, in the present embodiment, each terminal attachment member 60 is connected to the lower surface of the peripheral edge portion of the opening 24 of the external terminal 22. With this configuration, each terminal attachment member 60 is connected to the stretchable conductive layer 20 and therefore the first stretchable base 10 and other portions (except for the insulating coating 80) of the stretchable circuit board 100. No terminal attachment member 60 is connected to a location other than the lower surface of the peripheral edge portion of the opening 24 of the external terminal 22. Thus, in the present embodiment, it can be said that the terminal attachment member 60 is supported only by the portion (stretchable conductive layer 20 in the present embodiment) made of the material having stretchability. Of the stretchable conductive layer 20, the portion supporting the terminal attachment member 60 and the portion therearound (stretchable conductive layer 20 and first stretchable base 10) also have stretchability. Thus, each terminal attachment member 60 can easily move in the in-plane direction of the stretchable circuit board 100. Note that the insulating coating 80 does not have stretchability, for example. However, the insulating coating 80 is supported by the terminal attachment member 60 rather than supporting the terminal attachment member 60. Thus, the insulating coating 80 moves in the in-plane direction of the stretchable circuit board 100 along with the terminal attachment member 60.

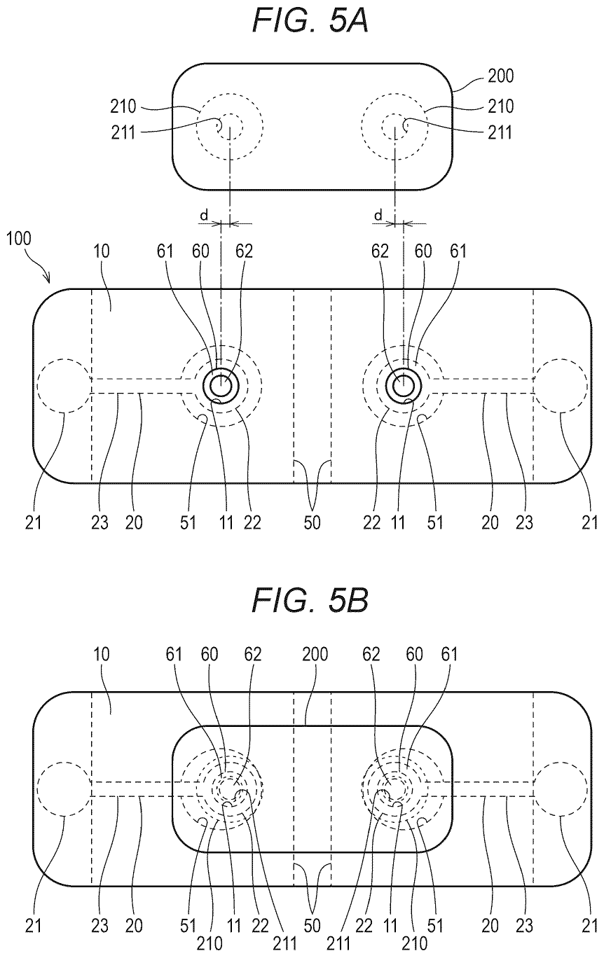

Next, operation will be described with reference to FIGS. 5A and 5B. When the stretchable circuit board 100 is in close contact with the skin, the stretchable circuit board 100 is curved along the curved shape of the skin of the biological body. Thus, when the stretchable circuit board 100 is shipped, even if the stretchable circuit board 100 has such a dimension that the location of each terminal attachment member 60 is coincident with the location of the corresponding attachment portion 210 of the external device 200, the location of each terminal attachment member 60 may be misaligned from the location upon shipping when the stretchable circuit board 100 is bonded to the skin. A distance d shown in FIG. 5A schematically indicates such a misaligned distance. In view of such a situation, according to the stretchable circuit board 100 of the present embodiment, each terminal attachment member 60 can easily move in the in-plane direction of the stretchable circuit board 100. Thus, for example, as shown in FIG. 5B, each terminal attachment member 60 can be moved to the location of the corresponding attachment portion 210. Then, each terminal attachment member 60 can be attached to the corresponding attachment portion 210. Note that when each terminal attachment member 60 moves in the in-plane direction of the stretchable circuit board 100, the stretchable conductive layer 20 and the first stretchable base 10 supporting the terminal attachment member 60 are stretched and contracted with the state of connection (mechanical and electrical connection state) between the terminal attachment member 60 and the stretchable conductive layer 20 maintained. When the stretchable conductive layer 20 and the first stretchable base 10 are stretched and contracted, the second stretchable base 30, the adhesive 50, and the biological conductive member 70 are also stretched and contracted.

### First Modification of First Embodiment

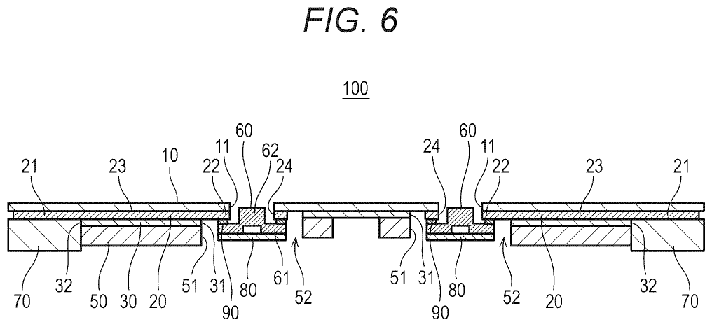

Next, a first modification of the first embodiment will be described with reference to FIG. 6. A stretchable circuit board 100 according to the present modification is different from the stretchable circuit board 100 according to the first embodiment above in the following points. On the other points, the stretchable circuit board 100 according to the present modification is similar to the stretchable circuit board 100 according to the first embodiment above.

In the example described in the first embodiment above, when the external terminal 22 and the terminal attachment member 60 are joined to each other, the silver paste coating film exhibiting thermoplasticity and hot-melt properties is welded by the method such as the hot-press method. In the present modification, in order to further improve reliability in joining between the external terminal 22 and the terminal attachment member 60, a tape member (conductive tape 90) having conductivity is interposed between the external terminal 22 and the terminal attachment member 60 as shown in FIG. 6. That is, the terminal attachment member 60 is bonded to the external terminal 22 through the conductive tape 90.

As shown in FIG. 6, the conductive tape 90 is formed in a circular ring shape so as to surround the projection 62, for example. That is, the upper surface of a peripheral edge portion of the flange 61 and the lower surface of the peripheral edge portion of the opening 24 of the external terminal 22 are bonded to each other through the conductive tape 90. The conductive tape 90 has, for example, adhesiveness on both surfaces, and has conductivity in the thickness direction. That is, the conductive tape 90 is, for example, an anisotropic conductive sheet. Note that the conductive tape 90 may be made of a material other than the anisotropic conductive sheet.

Note that the stiffness of the conductive tape 90 is set to an intermediate value between the stiffness of the terminal attachment member 60 (metal member made of iron, for example) and the stiffness of the stretchable conductive layer 20. Thus, the conductive tape 90 does not stretch and contract much as compared to the stretchable conductive layer 20. On the other hand, the conductive tape 90 has stretchability as compared to the substantially-rigid terminal attachment member 60. Thus, the conductive tape 90 functions as a so-called rigid buffer between the terminal attachment member 60 and the stretchable conductive layer 20. With this configuration, rupture of a portion of the stretchable conductive layer 20 in the vicinity of the terminal attachment member 60 can be reduced, for example.

### Second Modification of First Embodiment

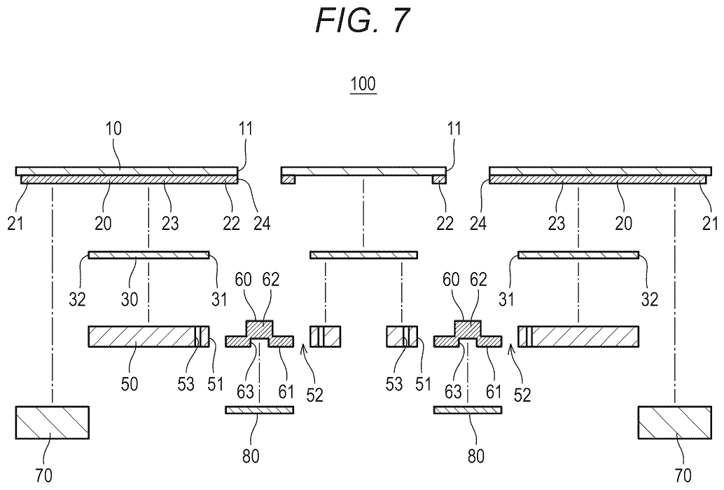

Next, a second modification of the first embodiment will be described with reference to FIG. 7. A stretchable circuit board 100 according to the present modification is different from the stretchable circuit board 100 according to the first embodiment above in the following points. On the other points, the stretchable circuit board 100 according to the present modification is similar to the stretchable circuit board 100 according to the first embodiment above. In the present modification, a slit 53 is formed around each terminal attachment member 60 in the adhesive 50. Thus, the terminal attachment member 60 can more easily move in the in-plane direction of the stretchable circuit board 100. The shape of the slit 53 is not particularly limited. Examples of the shape of the slit 53 include a circular ring shape surrounding the terminal attachment member 60 in plan view. Preferably, the slit 53 penetrates the adhesive 50 in the thickness direction thereof. Note that the slit 53 may be formed only in a partial area of the adhesive 50 in the thickness direction thereof. Note that the structure (structure having the adhesive 50 with the slit 53) of the present modification can also be employed in the first modification above.

### Second Embodiment

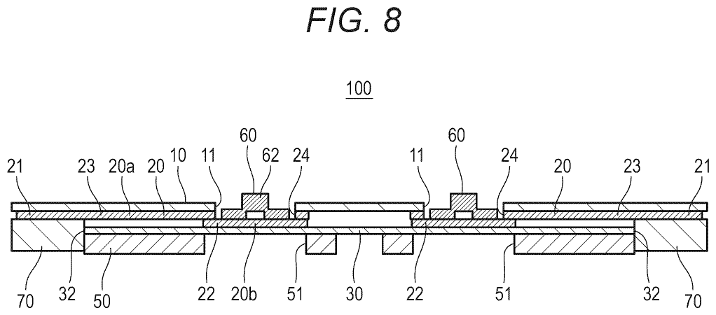

Next, a second embodiment will be described with reference to FIG. 8. A stretchable circuit board 100 according to the present embodiment is different from the stretchable circuit board 100 according to the first embodiment above in the following points. On the other points, such a stretchable circuit board 100 is similar to the stretchable circuit board 100 according to the first embodiment above.

As shown in FIG. 8, in the present embodiment, the external terminal 22 is formed on the surface of the second stretchable base 30 facing the first stretchable base 10. Moreover, the terminal attachment member 60 is provided on the upper surface of the external terminal 22. The terminal attachment member 60 is exposed to the upper surface side of the stretchable circuit board 100 through the opening 24 and the opening 11. That is, at the location at which the external terminal 22 is formed, the opening 11 is formed in the first stretchable base 10. The external terminal 22 is exposed on the first stretchable base 10 through the opening 11. At the location at which the biological electrode 21 is formed, the second stretchable base 30 is formed with the opening 32 (missing portion). The biological electrode 21 is exposed on the lower surface side of the stretchable circuit board 100 through the opening 32. Here, the lower surface means the surface opposite to the surface (upper surface) of the stretchable circuit board 100 facing the exposed surface of the external terminal 22. The terminal attachment member 60 is conductive, and is provided on the external terminal 22. The terminal attachment member 60 is exposed (to the upper surface side) through the opening 11 of the first stretchable base 10.

As described above, in the present embodiment, the stretchable conductive layer 20 includes a first portion 20a formed on the lower surface of the first stretchable base 10 and a second portion 20b formed on the upper surface of the second stretchable base 30. Of these portions, the first portion 20a has the biological electrode 21 and the wiring portion 23, and has the opening 24. The second portion 20b forms the external terminal 22.

The first portion 20a and the second portion 20b are welded to each other by hot-press, and are mechanically and electrically connected to each other. That is, the upper surface of a peripheral edge portion of the external terminal 22 (second portion 20b) is mechanically and electrically connected to the lower surface of the peripheral edge portion of the opening 24 of the first portion 20a.

The lower surface of the flange 61 of the terminal attachment member 60 and the upper surface of the second portion 20b may be similarly welded and fixed to each other by hot-press. Alternatively, as in the first modification above, a conductive tape may be interposed between the lower surface of the flange 61 of the terminal attachment member 60 and the upper surface of the second portion 20b.

More specifically, in the present embodiment, the inner diameter of the opening 11 and the inner diameter of the opening 24 are greater than the outer diameter of the terminal attachment member 60. In plan view, the entirety of the terminal attachment member 60 is within the opening 11 and the opening 24. Note that FIG. 8 shows a clearance as if the clearance is provided between the upper surface of the second stretchable base 30 and the lower surface (lower surface of the wiring portion 23) of the first portion 20a of the stretchable conductive layer 20. Actually, the second stretchable base 30 and the first portion 20a bend in a direction of approaching each other, and are in close contact with each other. Thus, the clearance shown in FIG. 8 is not substantially provided.

In the present embodiment, the lower surface side (biological body side) of the terminal attachment member 60 is covered with the second stretchable base 30. Thus, the insulating coating 80 in the first embodiment above can be omitted. The entire surface of the terminal attachment member 60 is supported by the external terminal 22. Thus, the terminal attachment member 60 can be more stably supported by the stretchable conductive layer 20 (particularly, external terminal 22).

### Third Embodiment

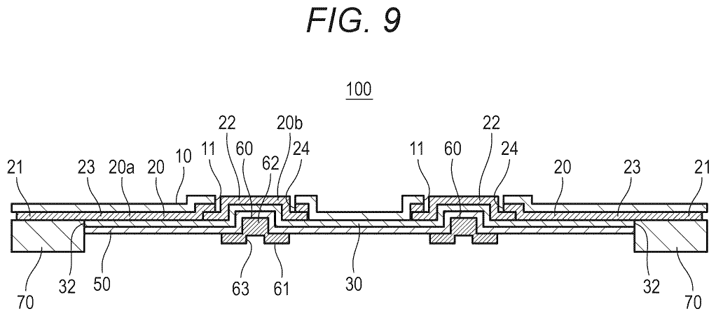

Next, a third embodiment will be described with reference to FIG. 9. A stretchable circuit board 100 according to the present embodiment is different from the stretchable circuit board 100 according to the second embodiment above in the following points. On the other points, such a stretchable circuit board 100 is similar to the stretchable circuit board 100 according to the second embodiment above.

In the present embodiment, the adhesive 50 has no opening 51. Moreover, the adhesive 50 is also provided at the location corresponding to the external terminal 22 and the location corresponding to the terminal attachment member 60. In the embodiments and modifications above, the structure with the two right and left divided adhesives 50 has been described as an example. On the other hand, in the present embodiment, for example, the entirety of the adhesive 50 is provided as one. Moreover, the terminal attachment member 60 is disposed on the lower surface side of the adhesive 50.

In the present embodiment, the projection 62 of the terminal attachment member 60 is supported by the adhesive 50. More specifically, the projection 62 is embedded in three layers including the adhesive 50, the second stretchable base 30, and the external terminal 22 in this order from below. The three layers including the adhesive 50, the second stretchable base 30, and the external terminal 22 have upwardly-projecting shapes reflecting the shape of the projection 62.

In the present embodiment, the adhesive 50 is interposed between the external terminal 22 and the terminal attachment member 60. The terminal attachment member 60 is attached to the attachment portion 210 through the adhesive 50 and the external terminal 22. That is, the terminal attachment member 60 is attached to the attachment portion 210 of the external device 200 through the adhesive 50 and the external terminal 22. With this configuration, the external terminal 22 contacts the connection terminal 211, and is electrically connected to the connection terminal 211.

More specifically, in the present embodiment, the opening 11 is formed in the first stretchable base 10 at the location at which the external terminal 22 is formed. The external terminal 22 is exposed (to the upper surface side) on the first stretchable base 10 through the opening 11. At the location at which the biological electrode 21 is formed, the opening 32 (missing portion) is formed in the second stretchable base 30. The biological electrode 21 is exposed to the lower surface side of the stretchable circuit board 100 through the opening 32. Here, the lower surface means the surface opposite to the surface (upper surface) of the stretchable circuit board 100 facing the exposed surface of the external terminal 22. The second stretchable base 30 and the adhesive 50 are interposed between the external terminal 22 and the terminal attachment member 60. The terminal attachment member 60 is attached to the attachment portion 210 of the external device 200 through the adhesive 50, the second stretchable base 30, and the external terminal 22. Note that the total of the thickness dimensions of the adhesive 50, the second stretchable base 30, and the external terminal 22 covering the terminal attachment member 60 is, for example, less than 100 μm. On the other hand, the upper-lower dimension of the projection 62 of the terminal attachment member 60 is, for example, 0.5 mm (500 μm) or more. Thus, even in a case where the adhesive 50, the second stretchable base 30, and the external terminal 22 are interposed between the projection 62 and the connection terminal 211, the projection 62 can be fitted in the connection terminal 211.

In the present embodiment, the terminal attachment member 60 is not electrically connected to any member. Thus, the conductivity of the terminal attachment member 60 is not essential. The terminal attachment member 60 is only required to have magnetic properties. In terms of a cost and machinability, an iron material is suitably used as the material of the terminal attachment member 60. Note that iron tends to be rusted due to external environment. Thus, in many cases, the periphery of the iron material is plated with nickel. Considering influence of nickel on the biological body, the outer surface of the terminal attachment member 60 (including the nickel-plated layer) is preferably coated with an insulating coating material.

In the present embodiment, the adhesive 50 preferably has a single-film structure with adhesive resin. With this configuration, the terminal attachment member 60 can easily move in the plane of the stretchable circuit board.

Note that in the present embodiment, a clearance may be provided between the periphery (side) of a portion (projection 62 and flange 61) of the terminal attachment member 60 embedded in or contacting the adhesive 50 and the adhesive 50. With such a clearance, each terminal attachment member 60 can more easily move in the in-plane direction of the stretchable circuit board 100. For example, an air layer may be interposed between the flange 61 and the adhesive 50 at the periphery of the projection 62. With the air layer, each terminal attachment member 60 can more easily move in the in-plane direction of the stretchable circuit board 100.

### Fourth Embodiment

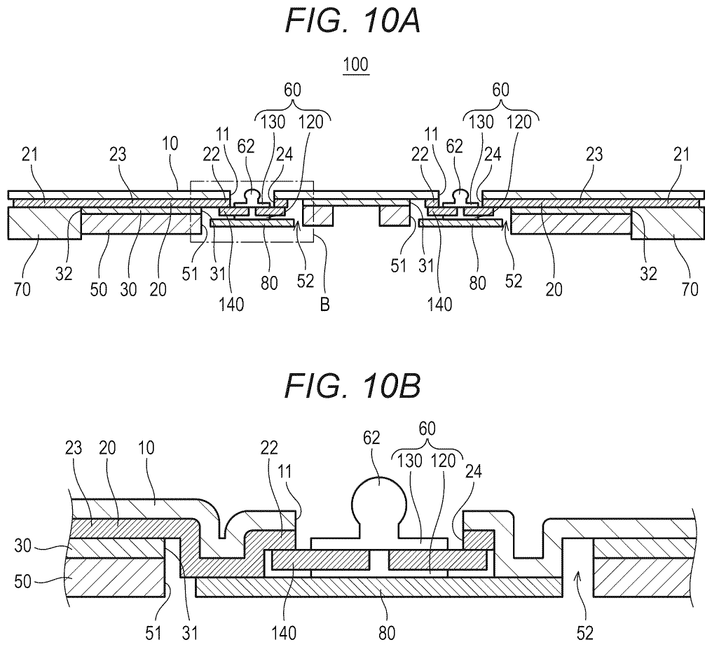

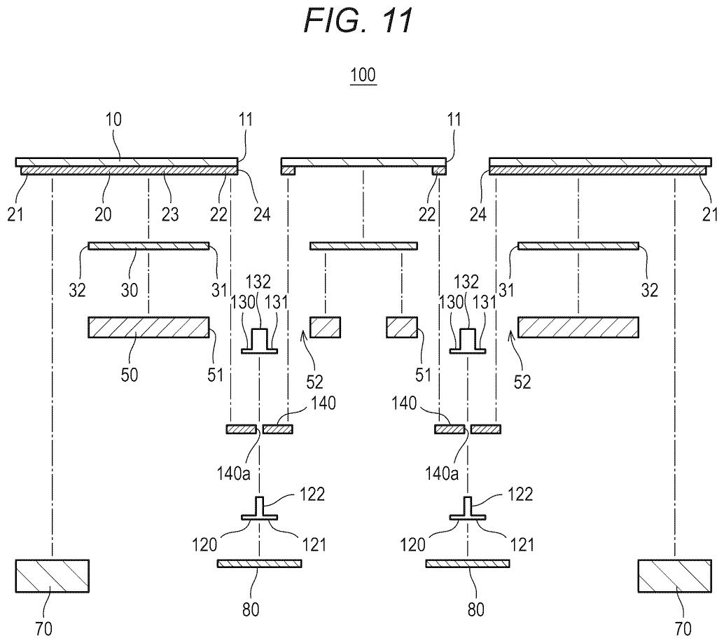

Next, a fourth embodiment will be described with reference to FIGS. 10A to 11. A stretchable circuit board 100 according to the present embodiment is different from the stretchable circuit board 100 according to the first embodiment above in the following points. On the other points, such a stretchable circuit board 100 is similar to the stretchable circuit board 100 according to the first embodiment above.

In the examples described in the embodiments and modifications above, the terminal attachment member 60 is supported only by the portions of the other members having stretchability. On the other hand, in the present embodiment, the terminal attachment member 60 is supported by a member (insulating coating 80 described below) made of a non-stretchable material. The terminal attachment member 60 is configured to move in the in-plane direction of the stretchable circuit board 100 integrally with the insulating coating 80.

In the present embodiment, for example, as shown in FIG. 11, the terminal attachment member 60 includes a first member 120 and a second member 130 swaged to each other. The first member 120 includes a flange 121 and a tubular portion 122 projecting upward from a center portion of the flange 121. The upper end of the tubular portion 122 is opened (has an opening), for example. The second member 130 includes a flange 131 and a tubular portion 132 projecting upward from a center portion of the flange 131. The upper end of the tubular portion 132 is closed. A non-stretchable conductive layer 140, which is a conductive layer with non-stretchability, is interposed between the flange 121 and the flange 131. An insertion hole 140a is formed so as to penetrate a center portion of the non-stretchable conductive layer 140 up and down. For example, a conductive washer may be used as the non-stretchable conductive layer 140.

The first member 120 and the second member 130 are swaged to each other, for example, by the following method. First, the second member 130 is disposed above the non-stretchable conductive layer 140 with the tubular portion 132 facing up and the flange 131 facing down. Subsequently, the tubular portion 122 of the first member 120 projects upward of the non-stretchable conductive layer 140 from below the non-stretchable conductive layer 140 through the insertion hole 140a. Then, the tubular portion 122 is fitted in the tubular portion 132 from below the flange 131. In this manner, the first member 120 and the second member 130 are swaged to each other. Thus, the tubular portion 132 is deformed to a spherical shape projecting upward as shown in FIG. 10, for example. The upper surface of the flange 121 is in pressure contact with the lower surface of the non-stretchable conductive layer 140. Moreover, the lower surface of the flange 131 is in pressure contact with the upper surface of the non-stretchable conductive layer 140. The second member 130 and therefore the entirety of the terminal attachment member 60 including the second member 130 and the first member 120 is electrically connected to the non-stretchable conductive layer 140.

The upper surface of a peripheral edge portion of the non-stretchable conductive layer 140 is mechanically and electrically connected to (in pressure contact with) the lower surface of the peripheral edge portion of the opening 24 of the external terminal 22. With this configuration, the stretchable conductive layer 20 is electrically connected to the terminal attachment member 60 through the non-stretchable conductive layer 140.

For the sake of convenience in illustration, in FIG. 10A, the stretchable conductive layer 20 and the insulating coating 80 are separated from each other in the upper-lower direction. Note that the first stretchable base 10 and the stretchable conductive layer 20 are extremely flexible. Thus, actually, part of the first stretchable base 10 and part of the stretchable conductive layer 20 deform and bend in a direction (downward) perpendicular to the plane, for example, as shown in FIG. 10B. Thus, at these parts, the lower surface of the stretchable conductive layer 20 or the lower surface of the first stretchable base 10 is in pressure contact with the upper surface of a portion of the insulating coating 80 protruding from the periphery of the first member 120 and the periphery of the non-stretchable conductive layer 140. Note that in FIG. 10B, not the stretchable conductive layer 20, but the first stretchable base 10 is in pressure contact with the portion of the insulating coating 80 protruding rightward of the first member 120 and the non-stretchable conductive layer 140. Note that the stretchable conductive layer 20 may also be in pressure contact with the portion of the insulating coating 80 protruding rightward of the first member 120 and the non- stretchable conductive layer 140 according to the area where the stretchable conductive layer 20 is formed.

In the present embodiment, the tubular portion 132 (projection) of the second member 130 is elastically fitted (with spring force) in the recess of the connection terminal 211 of the external device 200. Thus, the terminal attachment member 60 and the attachment portion 210 do not necessarily attract each other with the magnetic force.

In the present embodiment, each terminal attachment member 60 can move in the in-plane direction of the stretchable circuit board 100 integrally with the entirety of the insulating coating 80 (insulating coating 80 and non-stretchable conductive layer 140).

The embodiments and the modifications have been described above with reference to the drawings. Note that these embodiments and modifications are exemplary embodiments. Various configurations other than the configurations disclosed in the embodiments and modifications above may also be employed as the present embodiments.

For example, the structure including the terminal attachment member 60 bonded to the stretchable conductive layer 20 through the conductive tape 90 as in the first modification above can also be employed in the second, third, and fourth embodiments and the second modification above. Moreover, the structure including the slit 53 formed around the terminal attachment member 60 in the adhesive 50 as in the second modification above can also be employed in the second, third, and fourth embodiments above.

The terminal attachment member 60 of such a type that the two members (first member 120 and second member 130) are swaged to each other through the sheet as described in the fourth embodiment may be applied to an embodiment other than the fourth embodiment above. That is, for example, the first member 120 and the second member 130 may sandwich the external terminal 22 in the upper-lower direction. In this manner, the terminal attachment member 60 including the first member 120 and the second member 130 can be fixed to the external terminal 22. Moreover, the terminal attachment member 60 can be mechanically and electrically connected to the external terminal 22.

The terminal attachment member 60 may be of a type other than those described above. For example, the terminal attachment member 60 may have a shape corresponding to the upper second member 130 of the terminal attachment member 60 shown in FIGS. 10A and 10B. In this case, the lower surface of the flange 131 of the terminal attachment member 60 is mechanically and electrically connected to the stretchable conductive layer 20, for example, by thermal compression bonding or the conductive tape 90. In this case, the terminal attachment member 60 is also elastically fitted in the attachment portion 210 as in the fourth embodiment. Thus, the terminal attachment member 60 and the attachment portion 210 do not necessarily attract each other with the magnetic force. For example, in a case where the terminal attachment member 60 is the magnetic force attraction type member described in the first embodiment, the terminal attachment member of such a type that the two members are swaged to each other through the sheet as described in the fourth embodiment may be employed. The terminal attachment member 60 and the attachment portion 210 do not necessarily have the fitting structure. That is, the terminal attachment member 60 and the attachment portion 210 may be attached to each other only with the magnetic force.

The present embodiment includes technical ideas described below.
(A1) A stretchable circuit board including: a first stretchable base; a stretchable conductive layer; a second stretchable base; an adhesive; a plurality of biological electrodes; a plurality of external terminals; and a plurality of terminal attachment members, in which each of the plurality of biological electrodes and each of the plurality of external terminals are included in the stretchable conductive layer, the second stretchable base is disposed so as to face the first stretchable base with the stretchable conductive layer interposed therebetween, the adhesive is configured to fix the stretchable circuit board to a biological body, each of the plurality of terminal attachment members is attached to an attachment portion of a corresponding connection terminal of external device to electrically connect the external terminals to the connection terminals of the external device, at least a biological-body-side surface of each terminal attachment member is exposed on the adhesive, and each terminal attachment member is movable in an in-plane direction of the stretchable circuit board.
(A2) The stretchable circuit board according to (A1), in which the adhesive has a portion corresponding to each external terminal and each terminal attachment member, and the corresponding portion is formed with an opening.
(A3) The stretchable circuit board according to (A2), in which a clearance is provided between an inner peripheral edge of the opening of the adhesive and an outer peripheral surface of each terminal attachment member.
(A4) The stretchable circuit board according to (A1) to (A3), in which each terminal attachment member is conductive, the first stretchable base and each external terminal are formed with openings, each terminal attachment member is connected to a peripheral edge portion of the opening of each external terminal, part of each terminal attachment member is exposed through the openings of the first stretchable base and each external terminal, and the part of each terminal attachment member is attached to the attachment portion of the connection terminal of the external device to electrically connect each external terminal to the corresponding connection terminal of the external device through a corresponding one of the terminal attachment members.
(A5) The stretchable circuit board according to (A1) to (A3), further including: an insulating coating covering the biological-body-side surface of each terminal attachment member.
(A6) The stretchable circuit board according to (A1) or (A2), in which the first stretchable base is formed with an opening at a location at which each external terminal is provided, each external terminal is exposed on an upper surface side of the stretchable circuit board on the first stretchable base through the opening of the first stretchable base, the second stretchable base is formed with an opening at a location at which each biological electrode is provided, each biological electrode is exposed on a lower surface side of the stretchable circuit board through the opening of the second stretchable base, and each terminal attachment member is conductive, is provided on a corresponding one of the external terminals, and is further exposed through the opening of the first stretchable base.
(A7) The stretchable circuit board according to (A1) to (A6), in which the adhesive has a single-film structure with adhesive resin.
(A8) The stretchable circuit board according to (A1), in which the adhesive is interposed between each external terminal and each terminal attachment member, and each terminal attachment member is attached to the attachment portion of the connection terminal of the external device through the adhesive and a corresponding one of the external terminals.
(A9) The stretchable circuit board according to (A8), in which each terminal attachment member is supported by the adhesive.
(A10) The stretchable circuit board according to (A8) or (A9), in which the first stretchable base is formed with an opening at a location at which each external terminal is provided, each external terminal is exposed on an upper surface side of the stretchable circuit board on the first stretchable base through the opening of the first stretchable base, the second stretchable base is formed with an opening at a location at which each biological electrode is provided, each biological electrode is exposed on a lower surface side of the stretchable circuit board through the opening of the second stretchable base, the second stretchable base and the adhesive are interposed between each external terminal and each terminal attachment member, and each terminal attachment member is attached to the attachment portion of the connection terminal of the external device through the adhesive, the second stretchable base, and a corresponding one of the external terminals.
(A11) The stretchable circuit board according to (A1) to (A7), in which each terminal attachment member is attached to a corresponding one of the external terminals through a conductive tape.

Note that in a case where the terminal attachment member 60 is attached to the attachment portion 210 of the external device 200 through the adhesive 50 and the external terminal 22 as in the structure disclosed in the third embodiment above, the terminal attachment member 60 is not necessarily movable in the in-plane direction of the stretchable circuit board 100. That is, the present embodiment includes the following technical ideas.
(B1) A stretchable circuit board including: a first stretchable base; a stretchable conductive layer; a second stretchable base; an adhesive; a biological electrode; a external terminal; and a terminal attachment member, in which the biological electrode and the external terminal are included in the stretchable conductive layer, the second stretchable base is disposed so as to face the first stretchable base with the stretchable conductive layer interposed therebetween, the adhesive is configured to fix the stretchable circuit board to a biological body, and the terminal attachment member is attached to an attachment portion of a connection terminal of an external device to electrically connect the external terminal to the connection terminal of the external device. The adhesive is interposed between the external terminal and the terminal attachment member, and the terminal attachment member is attached to the attachment portion of the connection terminal of the external device through the adhesive and the external terminal.
(B2) The stretchable circuit board according to (B1), in which the terminal attachment member is supported by the adhesive.
(B3) The stretchable circuit board according to (B1) or (B2), in which the first stretchable base is formed with an opening at a location at which the external terminal is provided, the external terminal is exposed on an upper surface side of the stretchable circuit board on the first stretchable base through the opening of the first stretchable base, the second stretchable base is formed with an opening at a location at which the biological electrode is provided, the biological electrode is exposed on a lower surface side of the stretchable circuit board through the opening of the second stretchable base, the second stretchable base and the adhesive are interposed between the external terminal and the terminal attachment member, and the terminal attachment member is attached to the attachment portion of the connection terminal of the external device through the adhesive, the second stretchable base, and the external terminals.
(B4) The stretchable circuit board according to (B1) to (B3), in which the adhesive has a single-film structure with adhesive resin.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A stretchable circuit board comprising:
a first stretchable base;
a stretchable conductive layer;
a second stretchable base;
an adhesive;
a plurality of biological electrodes;
a plurality of external terminals; and
a plurality of terminal attachment members,
wherein each of the plurality of biological electrodes and each of the plurality of external terminals are included in the stretchable conductive layer,
the second stretchable base is disposed so as to face the first stretchable base with the stretchable conductive layer interposed therebetween,
the adhesive is configured to fix the stretchable circuit board to a biological body,
each of the plurality of terminal attachment members is attached to an attachment portion of a corresponding connection terminal of external device to electrically connect the external terminals to the connection terminals of the external device,
at least a biological-body-side surface of each terminal attachment member is exposed on the adhesive, and
each terminal attachment member is movable in an in-plane direction of the stretchable circuit board.

2. The stretchable circuit board according to claim 1, wherein
the adhesive has a portion corresponding to each external terminal and each terminal attachment member, and
the corresponding portion is formed with an opening.

3. The stretchable circuit board according to claim 2, wherein
a clearance is provided between an inner peripheral edge of the opening of the adhesive and an outer peripheral surface of each terminal attachment member.

4. The stretchable circuit board according to claim 1, wherein
each terminal attachment member is conductive,
the first stretchable base and each external terminal are formed with openings,
each terminal attachment member is connected to a peripheral edge portion of the opening of each external terminal,
part of each terminal attachment member is exposed through the openings of the first stretchable base and each external terminal, and
the part of each terminal attachment member is attached to the attachment portion of the connection terminal of the external device to electrically connect each external terminal to the corresponding connection terminal of the external device through a corresponding one of the terminal attachment members.

5. The stretchable circuit board according to claim 1, further comprising:
an insulating coating covering the biological-body-side surface of each terminal attachment member.

6. The stretchable circuit board according to claim 1, wherein
the first stretchable base is formed with an opening at a location at which each external terminal is provided,
each external terminal is exposed on an upper surface side of the stretchable circuit board on the first stretchable base through the opening of the first stretchable base,
the second stretchable base is formed with an opening at a location at which each biological electrode is provided,
each biological electrode is exposed on a lower surface side of the stretchable circuit board through the opening of the second stretchable base, and
each terminal attachment member is conductive, is provided on a corresponding one of the external terminals, and is further exposed through the opening of the first stretchable base.

7. The stretchable circuit board according to claim 1, wherein
the adhesive has a single-film structure with adhesive resin.

8. The stretchable circuit board according to claim 1, wherein
the adhesive is interposed between each external terminal and each terminal attachment member, and
each terminal attachment member is attached to the attachment portion of the connection terminal of the external device through the adhesive and a corresponding one of the external terminals.

9. The stretchable circuit board according to claim 8, wherein
each terminal attachment member is supported by the adhesive.

10. The stretchable circuit board according to claim 8, wherein
the first stretchable base is formed with an opening at a location at which each external terminal is provided,
each external terminal is exposed on an upper surface side of the stretchable circuit board on the first stretchable base through the opening of the first stretchable base,
the second stretchable base is formed with an opening at a location at which each biological electrode is provided,
each biological electrode is exposed on a lower surface side of the stretchable circuit board through the opening of the second stretchable base, and
the second stretchable base and the adhesive are interposed between each external terminal and each terminal attachment member, and
each terminal attachment member is attached to the attachment portion of the connection terminal of the external device through the adhesive, the second stretchable base, and a corresponding one of the external terminals.

11. The stretchable circuit board according to claim 1, wherein
each terminal attachment member is attached to a corresponding one of the external terminals through a conductive tape.
